(19) United States
(12) Patent Application Publication
(10) Pub. No.: US 2016/0274180 A1
(43) Pub. Date: Sep. 22, 2016

(54) Embedded stress test circuitry and method of operating thereof

(71) Applicant: FREESCALE SEMICONDUCTOR, INC., Austin, TX (US)

(72) Inventors: XAVIER FRANÇOIS MARIE HOURS, TOURNEFEUILLE (FR); GUILLAUME JEAN FOUNAUD, SAINT ORENS DE GAMEVILLE (FR); MEHUL DILIPKUMAR SHROFF, AUSTIN, TX (US)

(21) Appl. No.: 14/830,924

(22) Filed: Aug. 20, 2015

(30) Foreign Application Priority Data
Mar. 20, 2015 (IB) PCT/IB2015/000529

(51) Int. Cl. G01R 31/28

(52) U.S. Cl. CPC G01R 31/2817; G01R 31/2818

(57) ABSTRACT

The present application relates to an embedded stress test circuitry for being formed on a substrate together with an operating circuit, both forming an electronic circuit. The embedded stress test circuitry comprises a test controller, a stress voltage regulator, which is controllably coupled to the test controller and arranged to generate a stress voltage signal in accordance with a stress voltage profile, a sensor, which is coupled to a component of the operating circuit and a storage, which is coupled to the test controller for storing the stress voltage profile.

### FIELD OF THE INVENTION

The invention relates to the test systems for integrated circuits, and more particularly, an embedded stress test circuity for integrated into complex circuitry for performing stressing of the complex circuitry in order to not do burn-in.

### BACKGROUND

To estimate the operable life of integrated circuits, they undergo burn-in testing. During burn-in testing, excess stresses are applied to the integrated circuits. This type of testing accelerates aging of the integrated circuits to determine to a reasonable certainty whether the integrated circuits will perform as expected for their anticipated life.

Burn-in testing is typically performed at the wafer-level, i.e., before the integrated circuits are packaged and/or at the package-level, i.e., after the integrated circuits are packaged. The packaged integrated circuits are placed on one or more burn-in test boards, each of which includes burn-in test circuits and pads for receiving various types of test voltages. The burn-in test circuits include burn-in instructions for operating the integrated circuits and for collecting and evaluating data therefrom.

Burn-in testing may be conducted for specified periods of time in a way that exposes “infant mortality failures”. The integrated circuits that fail as a result of fabrication variation, and those that fail early in the test procedure, indicate a much earlier than expected failure if used under operating conditions. Burn-in testing can also be used to expose integrated circuits that do not apparently have fabrication flaws, but nevertheless, would fail at unexpectedly early times in their service lives.

Burn-in testing of integrated circuits using external test equipment and test boards is a slow and expensive process. Moreover, burn-in testing is not available during service lives of the integrated circuits.

### SUMMARY

The present invention provides an embedded stress test circuitry and a method of operating thereof. Specific embodiments of the invention are set forth in the dependent claims. These and other aspects of the invention will be apparent from and elucidated with reference to the embodiments described hereinafter.

### BRIEF DESCRIPTION OF THE DRAWINGS

The accompanying drawings, which are incorporated herein and form a part of the specification, illustrate the present invention and, together with the description, further serve to explain the principles of the invention and to enable a person skilled in the pertinent art to make and use the invention.

FIG. 1 schematically illustrates a simplified block diagram showing an embedded stress test circuitry integrated into an electronic circuitry according to an example of the present invention;

FIG. 2 schematically illustrates a simplified block diagram showing a representative component under test of the operating circuit according to an example of the present invention;

FIG. 3 schematically illustrates a simplified block diagram showing an embedded stress test circuitry according to an example of the present invention;

FIG. 4 schematically illustrates a look-up table showing parameters and settings representative of individual stress testing procedures according to an example of the present invention;

FIG. 5 schematically illustrates profile diagrams showing individual stress voltage profiles applicable for stress testing procedures according to an example of the present invention; and

FIG. 6 schematically illustrates a state diagram of an embedded stress test circuitry according to an example of the present invention.

### DETAILED DESCRIPTION

In the following, embodiments are described with reference to the drawings wherein like reference numerals are generally utilized to refer to like elements throughout. In the following description, for purposes of explanation, numerous specific details are set forth in order to provide a thorough understanding of one or more aspects of embodiments. However, it may be evident to a person skilled in the art that one or more aspects of the embodiments may be practiced with a lesser degree of these specific details. The following description is therefore not to be taken in a limiting sense, and the scope of protection is defined by the appended claims.

The various aspects summarized may be embodied in various forms. The following description shows by way of illustration various combinations and configurations in which the aspects may be practiced. It is understood that the described aspects and/or embodiments are merely examples and that other aspects and/or embodiments may be utilized and structural and functional modifications may be made without departing from the scope of the present disclosure. In addition, while a particular feature or aspect of an embodiment may be disclosed with respect to only one of several implementations, such feature or aspect may be combined with one or more other features or aspects of the other implementations as it may be desired and advantageous for any given or particular application.

In the following, various methods and embedded stress test circuits are described separately or with reference to each other. It is understood that comments made in connection with a described method may also hold true for a corresponding embedded stress test circuit configured to perform the method and vice versa. For example, if a specific method step is described, a corresponding embedded stress test circuit may include a unit to perform the described method step, even if such a unit is not explicitly described or illustrated in the figures.

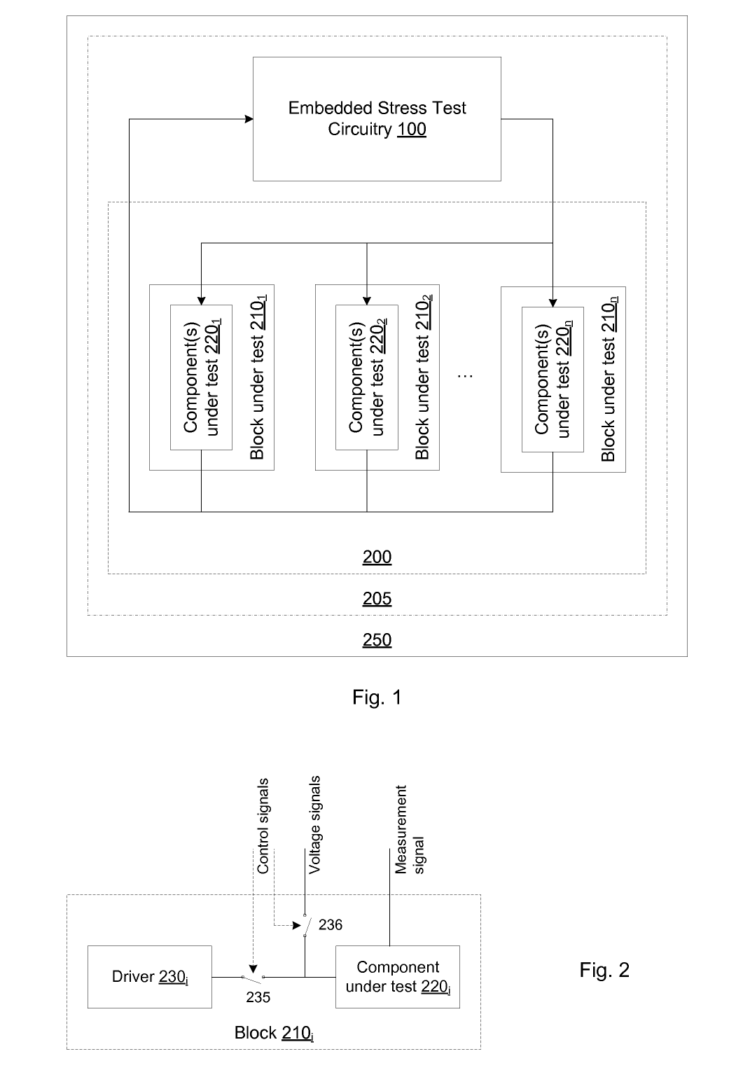

Referencing to FIG. 1, a simplified block diagram of an electronic circuit with an embedded burn-in test circuitry integrated therein is schematically shown. The electronic circuit 205 comprises an operating circuit 200 and the embedded stress test circuitry 100.

The electronic circuit 205 includes a substrate 250, in which the operating circuit 200 and the embedded stress test circuitry 100 are formed or on which the operating circuit 200 and the embedded stress test circuitry 100 are arranged. The substrate 250 is in particular a semiconductor substrate or a circuit board substrate. The electronic circuit 205 may be included in a package, which comprise a body formed of dielectric material, pins and/or contact pads positioned at the outer surface of the package, wherein the pins and/or contact pads interface electrically with the electronic circuit 205. The embedded stress test circuitry 100 is operable at any production level including wafer-level and/or package level as well as during use-level of the operating circuit 200.

The embedded stress test circuitry 100 causes the operating circuitry 200 to operate and generate data related thereto. The embedded stress test circuitry 100 includes one or more sets of stress test instructions. In particular, a set of stress test instructions comprises a set of predefined instructions for the operating circuitry 210 or a part thereof to operate the operating circuitry 210 or a part thereof under specifically defined stress test conditions under control of the embedded stress test circuitry 100.

More particularly, the operating circuitry 210 may comprise at least one component, to which a stress test is to be applied. The at least one component 220₁, 220₂, . . . , 220ₙ may be arranged in a functional block 210₁, 210₂, . . . , 210ₙ, which may be understood as a spatially separated or functional structure within the operating circuitry 210. A set of predefined instructions to the at least one component comprises instructions for operating various stress test stages to apply stress to the at least one component and to sense the effect of the stress applied thereto.

For purposes of illustration, the at least one component under test may be at least one transistor, such as a power MOSFET (metal oxide semiconductor field effect transistor), for example, and the embedded stress test circuitry 100 performs a gate leakage test (GLT) to the at least one transistor. Such a gate leakage test (GLT) comprises sensing the gate leakage current, applying a stress voltage signal to the gate and sensing the gate leakage current, where the difference of the sensed gate leakage currents is indicative of a defect of the gate structure. The embedded stress test circuitry 100 is controlled on the basis of the set of instructions to perform the gate leakage test (GLT).

In addition to the embedded stress test circuitry 100 operating the operating circuitry 210 for testing purpose and generating testing data related thereto, the embedded stress test circuitry 100 is arranged to store the generated testing related data. The embedded stress test circuitry 100 may include an internal memory, for example, for storing the generated testing related data. Additionally or alternately, the generated testing-related data may be stored in a memory separated from the embedded stress test circuitry 100. The embedded stress test circuitry 100 may also process the generated testing-related data for analysis and/or evaluation purpose.

Referring now to FIG. 2, a simplified block diagram of a representative component under test of the operating circuit is schematically shown. The illustrated component under test 220ᵢ should be understood to represent one or more interconnected components. In operational use, the component under test 220ᵢ is supplied by a driver 230ᵢ. During a stress testing procedure conducted on the component under test 220ᵢ the driver 230ᵢ is disconnected from the component under test 220ᵢ by a switching component 235 receiving a control signal from the embedded stress test circuitry 100 to isolate the component under test 220ᵢ and/or to protect other components of the operating circuit 200. During the stress testing procedure, the component under test 220ᵢ is supplied with an operating voltage signal and/or a stress voltage signal provided by the embedded stress test circuitry 100. The operating voltage signal and/or a stress voltage signal provided by the embedded stress test circuitry 100 may be switchably connected to the component under test 220ᵢ via a switching component 236, which is controlled through a control signal provided by the embedded stress test circuitry 100.

The component under test 220ᵢ is coupled through a measurement line to the sensor of the embedded stress test circuitry 100 for generating test-related data representing an electric property to be monitored of the component under test 220ᵢ.

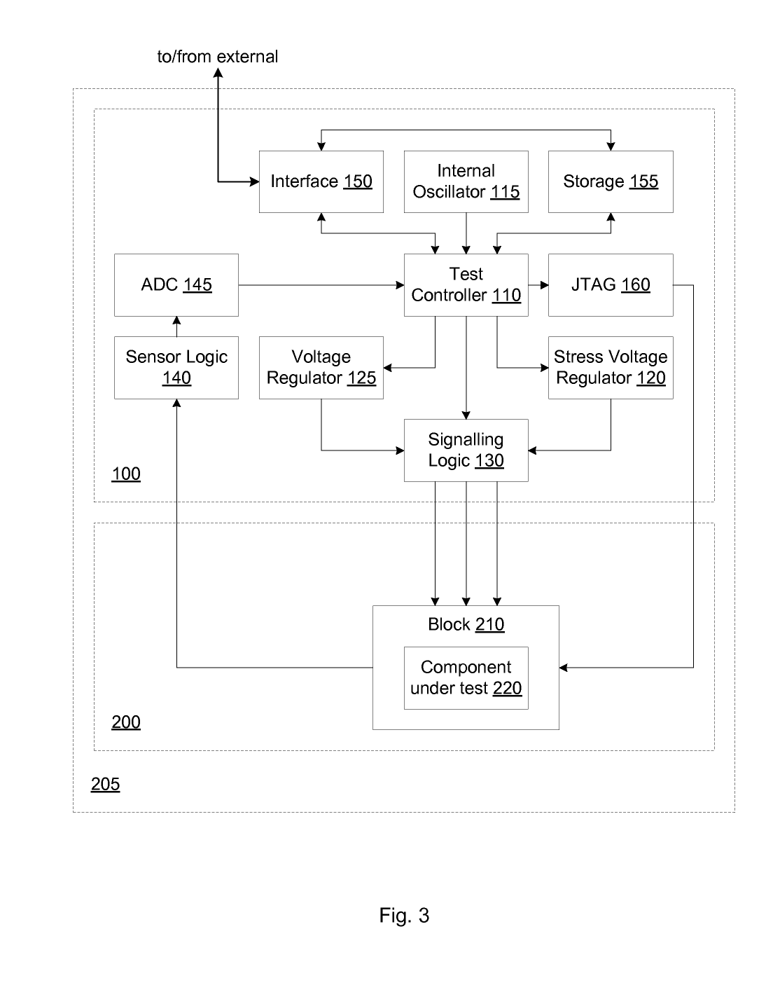

Now referring to FIG. 3, a schematic block diagram of an embedded stress test circuitry and components thereof according to an example of the present application is illustratively shown. The embedded stress test circuitry 100 is provided to be integrated together with an operating circuit 200 in an electronic circuit 205 preferably on a common substrate such as a semiconductor substrate or board substrate.

The embedded stress test circuitry 100 is provided to conduct stress testing on one or more block and/or one or more components thereof. For the sake of understanding, the following description will refer to one component under test 220. The component under test 220 should be understood to represent one or more components arranged in at least one block 210 of the operating circuit 200. Moreover, the one component under test 220 should be understood to represent one or more sets each comprising at least one component under test, where the stress testing is conducted simultaneously, sequentially, cyclically and/or separately on the sets or a combination of sets.

The embedded stress test circuitry 100 comprises a test controller 110, which may be a built-in self-test controller. The test controller 110 is implemented on the basis of a state machine and configurable to conduct different stress testing procedures, each of which adapted individually to a component under test 220. The test controller 110 may be clocked by an oscillator 115 to enable operation of the embedded stress test circuitry 100 independent and/or autonomous of the operational state and condition of the operating circuit 200, respectively. The independent operation of the embedded stress test circuitry 100 allows in particular for wafer-level and package-level testing but also for use-level testing.

In order to generate voltage signals for performing stress testing, the test controller 110 is coupled to one or more voltage regulators including for instance a stress voltage regulator 120 and a voltage regulator 125.

The test controller 110 is adapted to exercise control over the stress voltage regulator 120 and/or the voltage regulator 125. The stress voltage regulator 120 is provided to generate and output a stress voltage signal, which is to be applied to a component under test 220 of the operating circuit 200 for applying stress thereon. Under control of the test controller 110, the stress voltage regulator 120 is capable of generating different time-dependent stress testing profiles, in particular stress testing voltage profiles. The voltage regulator 120 may be controllable by the test controller 110 to control the output level, signal shape, signal duration and the like of the stress voltage signal.

The voltage regulator 125 is provided to generate and output an operating voltage signal, which may be applied to a component under test 220 of the operating circuit 200 in particular for measuring electrical properties thereof e.g. before and/or during and/or after stress testing. The voltage regulator 125 may be controllable by the test controller 110. The controllability thereof may comprise output level, signal shape, signal duration and the like of the operating voltage signal.

The stress voltage regulator 120 and the voltage regulator 125 enable to conduct stress testing procedures on the operating circuit 200 and the components to be tested thereof without supplying the operating circuit 200 with a power signal.

The test controller 110 is further coupled to a switching and signaling logic 130. The switching unit is coupled to the test controller 110 and the voltage regulators 120 and 125 to receive control signals and/or voltage signals therefrom and to selectively supply the received signals to the component under test 220. The signals outputted by the switching and signaling logic 130 comprise one or more voltage signals and one or more test control signals for performing a stress testing procedure on the component under test 220.

The test control signal may comprise a test-on signal used to indicate to the component under test or the block thereof that a stress testing procedure is active. The test-on signal may be a bi-level signal. The test-on signal may be used to enable the block of the components under test to prepare for stress testing. In particular, the preparation may include isolating component under test 220 and the block 210 thereof and/or protecting further one or more components of the block 220 during stress testing. The test-on signal may operate one or more isolation switches, which are arranged to switchably isolate the component under test 220 before stress is applied thereon. The test-on signal may operate one or more protection switches, which are arranged to switchably disconnect further components of the block 210 before stress is applied to the component under test 220.

The test control signal may comprise a stress-on signal used to indicate to the block 210 under that a stress voltage signal is applied. The stress-on signal may be a bi-level signal. The stress-on signal may switch the component under test 220 for accepting a voltage signal from the stress voltage regulator 120 and/or voltage regulator 125.

The test control signal may comprise a sensing-on signal used to indicate to the block 210 or components thereof that an electric property thereof is sensed. The sensing-on signal may be a bi-level signal. The sensing-on signal may switch the component under test 220 for sensing.

During conducting a stress testing procedure, the switching and signaling logic may supply the voltage signals of the stress voltage regulator 120 and voltage regulator 125 to the component under test 220. The voltage signals of the stress voltage regulator 120 and voltage regulator 125 may be selectively supplied in accordance with an individual stress testing procedure applicable for stress testing the component under test 220.

The embedded stress test circuitry 100 further comprises a sensor logic 140 including at least one sensor for sensing electrical properties of the component under test 220. The sensor logic 140 may include a current measuring sensor. As aforementioned, the current measuring sensor may be used to sense a gate leakage current of a transistor. The sensor logic 140 is coupled to an analog-to-digital converter (ADC) 145, which receives the sensor output from the sensor logic 140 and produces sensor sample data representing the digitized sensor output. The ADC 145 is coupled to the test controller 110 to supply the sensor sample data thereto.

As already described above, the embedded stress test circuitry 100 is arranged to store the generated testing-related data supplied in form of the sensor sampling data by the sensor logic 140 and the ADC 145. The embedded stress test circuitry 100 may include an internal memory 155 and/or may be connected to an external memory for storing the sensor sample data.

The memory of the embedded stress test circuitry 100 further stores data and instructions for conducting an individual stress test procedure on a specified component under test 220.

As described above, the test controller 110 is adapted to conduct stress testing procedures on one or more components under test. For conducting stress test procedures, the test controller 110 may comprise a testing section, which is configured to conduct the stress test procedures. The test controller 110 may be further adapted to analyze and evaluate the testing related data generated in response to a stress test procedure. An evaluation section of the test controller 110 may be configured to perform the analysis and evaluation of the generated testing related data.

The analysis and evaluation performed at the embedded stress test circuitry 100 for instance comprises reporting deficiencies, detecting deficiencies including recoverable deficiencies and unrecoverable failures and predicting probable future failures.

The embedded stress test circuitry 100 is further provided with an interface 150. The interface 150 is configured to communicate control and/or configuration requests.

Control requests received at the interface 150 enable to control the operation of the embedded stress test circuitry 100 and the test controller 110 thereof. A control request may for instance instruct the test controller to conduct a stress testing procedure on a component under test 220. The control request may include information specifying one or more components, on which stress testing should be applied. The control request may further include information specifying a specific stress testing procedure to be applied to a specified component under test 220.

Control requests received at the interface 150 enable to recall the generated testing related data stored by the embedded stress test circuitry 100.

Configuration requests received at the interface 150 enable to configure the test controller 110. Such configuration requests may be used to configure individual stress testing procedures for components under test, to configure the analysis and evaluation of the generated test-related data and/or to configure actions to be taken in response to the analysis and evaluation.

The interface 150 may support digital commutation such as serial data communication. The interface 150 may be an interface supporting any proprietary or standardized communication protocol.

The test controller 110 of the embedded stress test circuitry 100 may be further provided with a test interface, in particular a standardized test/debug interface such as a JTAG (Joint Test Action Group) interface, interfacing with operating circuit 200 or one or more functional blocks 210 thereof.

The test controller 110 may include a programmable processing unit such as a microcontroller unit (MCU) or microprocessor unit (MPU) that runs a set of testing instructions for conducting stress testing procedures and/or a set of evaluation instructions for analyzing and evaluating the generated test-related data collected in response to one or more conducted stress testing procedures.

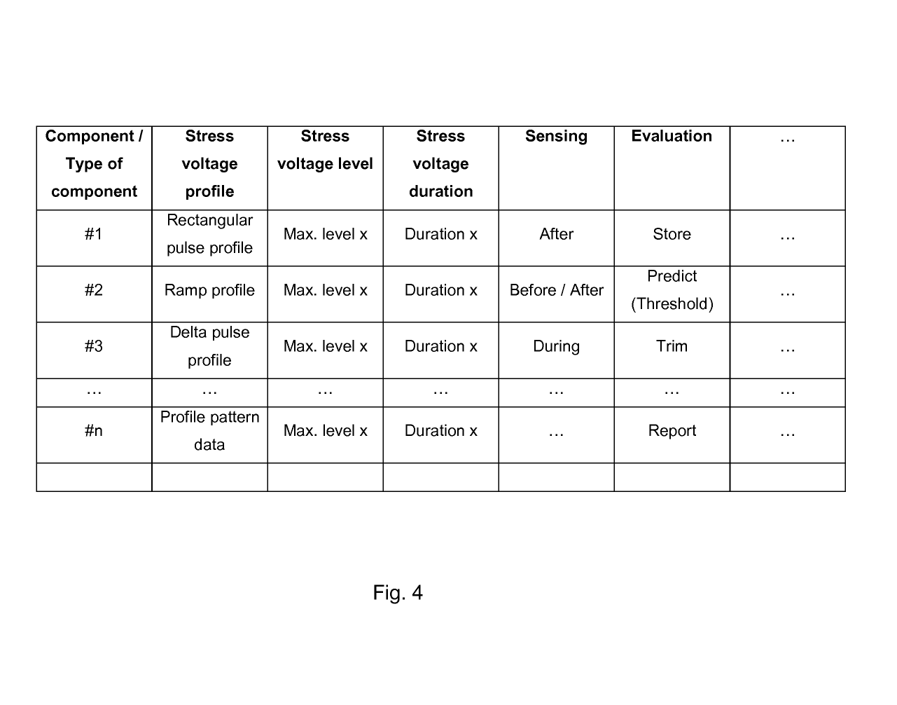

Referring to FIG. 4, a look-up table is schematically depicted for the sake of illustration of the configurability of the embedded stress test circuitry 100 and the test controller 110 thereof. The look-up table comprises a plurality of dataset entries #1 to #n each of which relates to a component or a set of components, to which an individual stress testing procedure can be applied by the embedded stress test circuitry 100.

As exemplarily illustrated, each dataset entry may comprise for instance one or more of the following exemplary entries:

a specific stress voltage pattern, wherein such as stress voltage pattern may comprise a predefined profile or may include a data pattern or function descriptive of a stress voltage pattern;

a stress voltage level, which may define one or more voltage levels in conjunction with the respective stress voltage pattern such as a maximum voltage level;

a stress voltage duration, which defines the duration of time during which the stress voltage is applied;

one or more sensing points in time, at which the electrical properties such as a current flow through the component(s) under test are sensed to generate test-related data recorded by the embedded stress test circuitry 100; and

an evaluation procedure, which is applied to the generated test-related data.

Each dataset entry may further include signal patterns to be applied through the JTAG interface.

It should be noted that the look-up table shown in FIG. 4 is merely illustrative to facilitate the understanding of the configurability of the embedded stress test circuitry 100 and the test controller 110 thereof. The present application should not be understood to be limited to the illustrated look-up table or the entries described with reference thereto. Those skilled in the art will understand that the look-up table is representative and descriptive of a configurable or programmable embedded stress test circuitry 100, which is enabled to apply individual stress testing procedure to a specific component or a specific set of components. Several individual stress testing procedures may be configured at the embedded stress test circuitry 100 on the basis of a set of instructions relating to the stress testing procedure and/or the analysis and evaluation procedure.

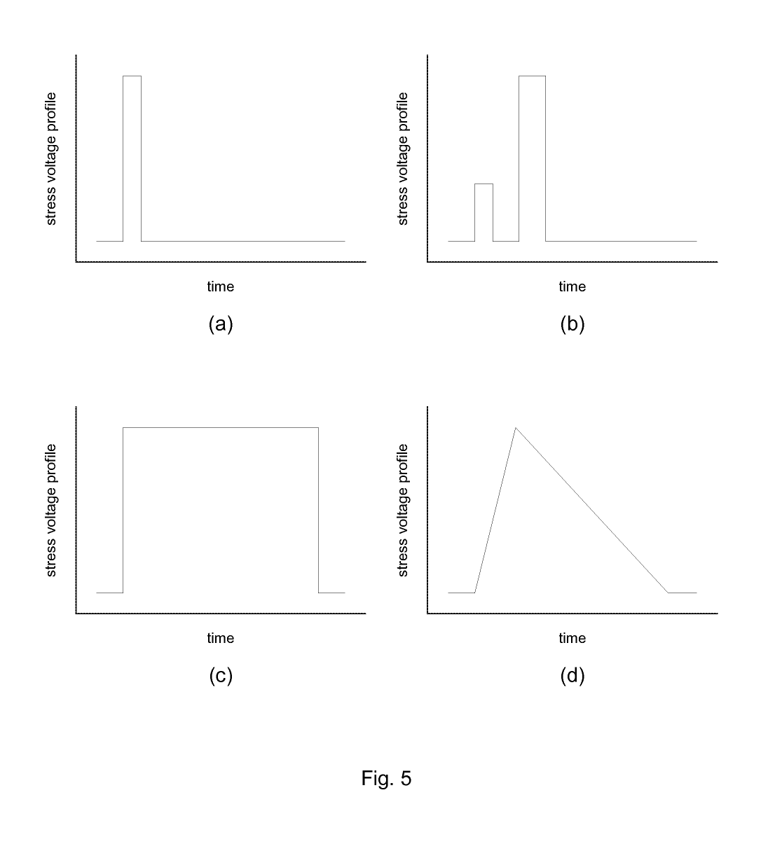

With reference to FIG. 5, exemplary stress voltage profiles are illustratively shown. The stress voltage profile should be understood to be merely representative and explanatory but not limiting. Those skilled in the art will understand that a stress voltage profile for being applied to a specific component or set of components. The top left profile (a) illustrates a delta pulse voltage profile and the bottom left profile (c) illustrates a rectangular voltage profile. The stress voltage profiles may include two or more pulses such as the top right profile (b). The bottom right profile (d) illustrates a ramp voltage profile.

The profiles may be predefined or may be defined on pattern data including for instance several data points each defining a voltage level at a point in time. The data points may be mapped to a predefined time scale and voltage level scale. Interpolation such as linear interpolation may be used to determine points between the data points of the pattern data.

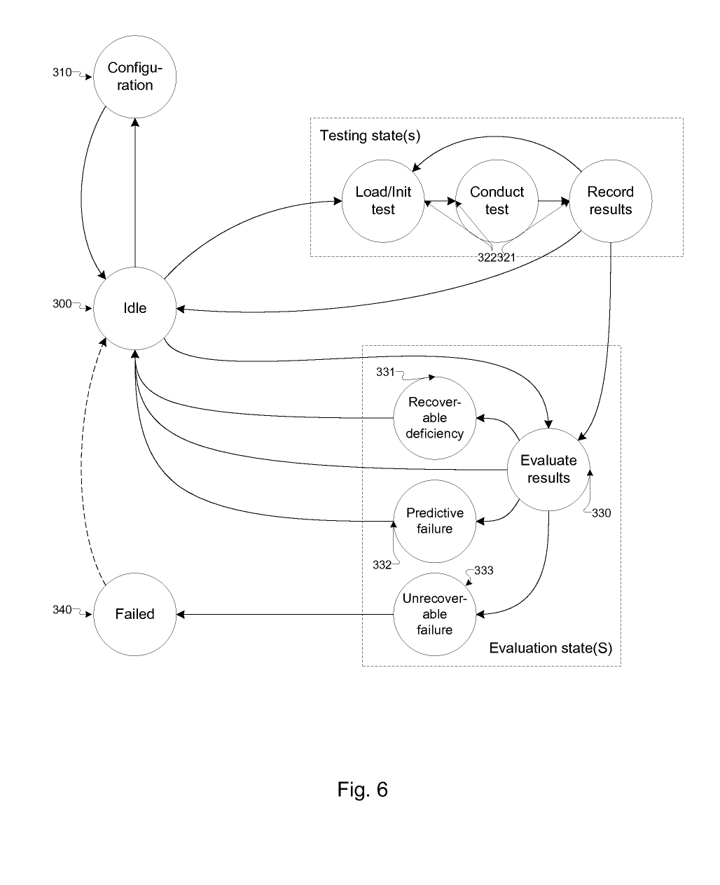

Referring now to FIG. 6, an illustrative state diagram of an embedded stress test circuitry 100 according to an example of the present application is schematically depicted. The exemplary embedded stress test circuitry 100 has four different operation states, an idle state 300, a failed state 340, a testing state 320 and an evaluation state 330.

In the idle state 300, the embedded stress test circuitry 100 is operative for instance to conduct one or more stress testing procedures, to evaluate recorded data relating to one or more previously conducted stress testing procedures, for (re-) configuration relating to stress testing procedures and/or analysis and evaluation procedures operable by the embedded stress test circuitry 100. The exemplary embedded stress test circuitry 100 may have a configuration state 310, in which the stress test circuitry 100 is enabled for (re-) configuration relating to stress testing procedures and/or analysis and evaluation procedures.

The embedded stress test circuitry 100 may transit to testing state 320 or evaluation state 330 upon a respective request received from external or upon a respective internally generated trigger signal.

For instance, the embedded stress test circuitry 100 may receive a control request via the interface 150, which instructs embedded stress test circuitry 100 to conduct one or more specified stress testing procedures on one or more components. The embedded stress test circuitry 100 may receive a control request via the interface 150, which instructs the embedded stress test circuitry 100 to perform an analysis and evaluation on the basis of data generated in the context of one or more stress testing procedures relating to sensed electrical properties of one or more components under test. The control request for performing an analysis and evaluation may specify one or more analysis and evaluation procedures to be applied.

In the testing state 320, the embedded stress test circuitry 100 is configured to initialize a stress testing procedure for applying stress on one or more components under test, cf. operation 321. The initialization may comprise loading instructions and data relating to the stress testing procedure to be conducted from the storage 155. After initialization, the stress testing procedure is conducted by the embedded stress test circuitry 100, cf. operation 322, which involves applying stress, such as a voltage stress signal and/or stress patterns, to the one or more components under test and sensing the effect caused by the applied stress. Sensing may involve sensing electrical properties of the one or more components under test before and/or during and/or after applying the stress thereon. The generated test-related data are recorded by the embedded stress test circuitry 100 and stored in the storage 155 for archiving and/or evaluation purposes, cf. operation S323.

The operations of the embedded stress test circuitry 100 in testing state may be repeated. After completion of the stress testing procedures to be conducted by the embedded stress test circuitry 100, the embedded stress test circuitry 100 may transit back to idle state or evaluation state.

In the evaluation state 330, data relating to one or more previously conducted stress tests are analyzed in accordance with one or more sets of instructions relating to an analysis and evaluation procedure, cf. operation 331. For instance, test-related data may be compared with one or more preconfigured threshold values and/or change of test-related data may be compared to one or more preconfigured threshold values. In particular, a first derivative with respect to time (corresponding to a rate of the change of a test-related value of the test-related data over time with respect to a test-related value recorded previously in time) or a second derivative with respect to time (corresponding to a change in time of the rate of change of a test-related value of test related-data) may be determined from a value of test-related data comprising analyzing the differences of a test-related value of the test-related data sensed and recorded at different points in time.

The analysis of the test-related data may yield to evaluation results indicative of deficiencies including for instance recoverable deficiencies, unrecoverable failures and/or predictive failures.

A recoverable deficiency may for instance be detected by an analysis and evaluation procedure, cf. operation 332. In response to the detection of the recoverable deficiency, the embedded stress test circuitry 100 may be configured

to deactivate or to initiate deactivating of one or more components identified as defective or one or more blocks comprising the one or more components identified as defective;

to activate or to initiate activating of one or more spare components or one or more spare blocks, which adopt the functionality of defective and/or deactivated components or blocks;

to trim or to initiate a trimming of one or more trimmable components or circuits; and/or

to switch or to initiate switching of the operating circuit into a fail-safe mode.

Those skilled in the art will understand that the above enumeration is exemplary and should not be understood as limiting the present application.

A predictive failure may for instance be detected by an analysis and evaluation procedure, cf. operation 333. The change of test-related data with respect to time (e.g. the first or second derivative) may exceed a preconfigured threshold, which is indicative of a continuing degradation of a component under test. Such detected continuing degradation of a component under test may be reported by the embedded stress test circuitry 100 to indicate that a failure of the continuingly degrading component has to be expected in (near) future.

An unrecoverable failure may for instance be detected by an analysis and evaluation procedure, cf. operation 334. The test-related data may exceed a threshold, which is indicative of a component under test operating outside of key operating parameters. In response to the detection of such an unrecoverable failure, the embedded stress test circuitry 100 may transit to the failed state.

In the failed state 340, the embedded stress test circuitry 100 may switch or to initiate switching of the operating circuit into a fail-safe mode. In the fail-safe mode, the operating circuit may continue to operate with reduced functionality.

Those skilled in the art will appreciate that the analysis and evaluation procedures may be performed while the test-related data is being recorded, or may be performed after the test-related data has been recorded.

Those skilled in the art will further appreciate that the embedded stress test circuitry 100 may be applicable to in-situ monitoring of the electrical properties of one or more components during operational use of the operating circuit. For in-situ monitoring, the embedded stress test circuitry 100 stores a history of the test-related data, on the basis of which, for instance, an aging of one or more components under test can be monitored. A history may comprise test-related data of a predefined number of stress testing procedures.

The embedded stress test circuitry 100 may conduct one or more stress testing procedures on one or more components of the operating circuit 200 while the operating circuit 200 is in a non-operative state for instance during manufacturing at wafer-level or at package-level but also at use-level when the operating circuit 200 is not powered.

More generally, an embedded stress test circuitry according to an example of the present application is provided for being formed on a substrate 250 together with an operating circuit 200, both forming an electronic circuit 205. The embedded stress test circuitry 100 comprises a test controller 110, a stress voltage regulator 125, which is controllably coupled to the test controller 110 and arranged to generate a stress voltage signal in accordance with a stress voltage profile, a sensor 140, which is coupled to a component 220 of the operating circuit 200 and a storage 155, which is coupled to the test controller 110 for storing the stress voltage profile.

The test controller 110 is configured to conduct a stress testing procedure on the component 220 by controlling the stress voltage regulator 125 in accordance with the at least one stress voltage profile retrieved from the storage 155, and to record test-related data sensed by the sensor 140 in response to the stress testing procedure.

According to an example of the present application, the storage 155 comprises a plurality of stress voltage profiles, each of which being adapted for conducting a stress testing procedure on a different component 220i.

According to an example of the present application, the test controller 110 is a configurable state machine, which is arranged to conduct the stress testing procedure in accordance with a set of instructions, which are stored at the storage 155 for being retrieved by the test controller 110 therefrom.

According to an example of the present application, the storage 155 comprises a plurality of sets of instructions, each of which being adapted for conducting a stress testing procedure on a different component 220i.

According to an example of the present application, the test controller 110 is arranged to conduct individual differing stress testing procedures, each of which adapted to at least one component 220 out of a plurality of components 220i.

According to an example of the present application, the component 220 comprises a single component or a plurality of interconnected components.

According to an example of the present application, the sensor 140 is adapted to sense an electric property of the at least one component under test 220.

According to an example of the present application, the test controller 110 is arranged to store the test-related data in the storage 155.

According to an example of the present application, the test controller 110 is arranged to evaluate the test-related data in accordance with an evaluation procedure to detect deficiencies of the component 220.

According to an example of the present application, a change of the test-related data in time is compared to a threshold in order to predict a prospective failure of the component upon exceeding of the threshold.

According to an example of the present application, the embedded stress test circuitry further comprises a signaling and switching logic 130, which is operatively coupled to the test controller 110. The signaling and switching logic 130 is arranged to output a control signal to the operating circuit 210 indicative of the stress testing procedure to be conducted by the test controller 110.

According to an example of the present application, the embedded stress test circuitry further comprises an analog-to-digital converter 145, which is coupled to the sensor 140 to receive a measurement signal therefrom and to generate test-related data based on the measurement signal.

According to an example of the present application, the embedded stress test circuitry further comprises a test interface 160, which is coupled to the test controller 110 and interfaces with a test interface of the operating circuit 200. The test controller 110 is arranged to transmit stress test patterns through the test interface 160 to the operating circuit 200.

According to an example of the present application, a circuitry is provided, which comprises an embedded stress test circuitry according to an example of the present application, an operating circuit 200 and a substrate 250, on or in which the embedded stress test circuitry (100) and the operating circuit (200) are formed.

In the foregoing specification, the invention has been described with reference to specific examples of embodiments of the invention. It will be evident, however, that various modifications and changes may be made therein without departing from the broader spirit and scope of the invention as set forth in the appended claims.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the disclosure herein may be implemented as electronic hardware, computer software, or combinations of both. To illustrate clearly this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation.

It will be further understood that the terms “comprises”, “comprising”, “includes” and/or “including”, The word “comprising” does not exclude the presence of other elements or steps then those listed in a claim. Furthermore, the terms “a” or “an”, as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an”. The same holds true for the use of definite articles. Unless stated otherwise, terms such as “first” and “second” are used to distinguish arbitrarily between the elements such terms describe. Thus, these terms are not necessarily intended to indicate temporal or other prioritization of such elements. The mere fact that certain measures are recited in mutually different claims does not indicate that a combination of these measures cannot be used to advantage.

1. An embedded stress test circuitry for being formed on a substrate together with an operating circuit, the embedded stress test circuitry comprising:
a test controller;
a stress voltage regulator controllably coupled to the test controller and arranged to generate a stress voltage signal in accordance with a stress voltage profile;
a sensor coupled to a component of the operating circuit; and
a storage coupled to the test controller for storing the stress voltage profile;
wherein the test controller is configured
to conduct a stress testing procedure on the component by controlling the stress voltage regulator in accordance with the at least one stress voltage profile retrieved from the storage, and
to record test-related data sensed by the sensor in response to the stress testing procedure.

2. The embedded stress test circuitry according to claim 1,
wherein the storage comprises a plurality of stress voltage profiles, each of which being adapted for conducting a stress testing procedure on a different component.

3. The embedded stress test circuitry according to claim 1,
wherein the test controller is a configurable state machine, which is arranged to conduct the stress testing procedure in accordance with a set of instructions, which are stored at the storage for being retrieved by the test controller therefrom.

4. The embedded stress test circuitry according to claim 1,
wherein the storage comprises a plurality of sets of instructions, each of which being adapted for conducting a stress testing procedure on a different component.

5. The embedded stress test circuitry according to claim 1,
wherein the test controller is arranged to conduct individual differing stress testing procedures, each of which adapted to at least one component out of a plurality of components.

6. The embedded stress test circuitry according to claim 1,
wherein the component comprises a single component or a plurality of interconnected components.

7. The embedded stress test circuitry according to anyone of the claim 1,
wherein the sensor is adapted to sense an electric property of the at least one component under test.

8. The embedded stress test circuitry according to claim 1,
wherein the test controller is arranged to store the test-related data in the storage.

9. The embedded stress test circuitry according to claim 1,
wherein the test controller is arranged to evaluate the test-related data in accordance with an evaluation procedure to detect deficiencies of the component.

10. The embedded stress test circuitry according to claim 1,
wherein a change of the test-related data in time is compared to a threshold in order to predict a prospective failure of the component upon exceeding of the threshold.

11. The embedded stress test circuitry according to claim 1, further comprising:
a signaling and switching logic operatively coupled to the test controller, wherein the signaling and switching logic is arranged to output a control signal to the operating circuit indicative of the stress testing procedure to be conducted by the test controller.

12. The embedded stress test circuitry according to claim 1, further comprising:
an analog-to-digital converter, which is coupled to the sensor to receive a measurement signal therefrom and to generate test-related data based on the measurement signal.

13. The embedded stress test circuitry according to claim 1, further comprising:
a test interface coupled to the test controller and interfacing with a test interface of the operating circuit, wherein the test controller is arranged to transmit stress test patterns through the test interface to the operating circuit.

14. A circuitry, comprising:
an embedded stress test circuitry according to claim 1; and
an operating circuit, and
a substrate, on which the embedded stress test circuitry and the operating circuit are formed or in which the embedded stress test circuitry and the operating circuit are formed.
